(19) United States
(12) Patent Application Publication
(10) Pub. No.: US 2004/0154165 A1
(43) Pub. Date: Aug. 12, 2004

(54) Method for manufacturing a probe pin and a probe card

(76) Inventors: Takehisa Takoshima, Tokyo (JP); Wataru Narazaki, Tokyo (JP); Seiichi Hata, Tokyo (JP); Akira Shimokohbe, Tokyo (JP)

Correspondence Address: Jonathan P. Osha, OSHA & MAY L.L.P., Suite 2800, 1221 McKinney Street, Houston, TX, 77010, US

(21) Appl. No.: 10/723,216

(22) Filed: Nov. 26, 2003

Related U.S. Application Data
(63) Continuation of application No. PCT/JP02/05102, filed on May 27, 2002.

(30) Foreign Application Priority Data
May 28, 2001 (JP) JP 2001-159629

(51) Int. Cl. H05K 3/02; H01R 43/00

(52) U.S. Cl. 29/846; 29/874; 29/857

(57) ABSTRACT

A method for manufacturing a probe card comprises the steps of forming a plurality of amorphous alloy layers of a predetermined shape at a predetermined substrate, wherein the amorphous alloy layer has a supercooled liquid temperature area, heating the amorphous alloy layer at the supercooled liquid temperature area, cooling the amorphous alloy layer at a temperature lower than the supercooled liquid temperature area and removing at least a part of the substrate in a state where the amorphous alloy layer is cooled at a temperature lower than the supercooled liquid temperature area.

The present application is a continuation application of PCT/JP02/05102 filed on May 27, 2002, which claims priority from a Japanese patent application Serial No. 2001-159629 filed on the date of May 28, 2001, the contents of which are incorporated herein by reference.

### BACKGROUND OF THE INVENTION

1. Field of the Invention

The present invention relates to a method manufacturing a probe pin and a method for manufacturing a probe card. More particularly, the present invention relates to a probe pin formed of an amorphous alloy. In addition, this patent application relates to the following Japanese patent application. In respect of the designated states, which approve the incorporation by referring to the documents, the contents of the following Japanese patent application are incorporated in this patent application by reference.

2. Related Art

There has conventionally been a probe card having a plurality of probe pins obtained by removing a silicon substrate after forming a metal layer having a predetermined shape on the silicon substrate.

In the conventional probe card, the metal layer has the internal stress when the metal layer is deposited on the silicon substrate during the manufacturing process. For this reason, when the silicon substrate was removed, it was impossible to hold the shape at the time of forming on the silicon substrate due to the internal stress, so that it is extremely difficult to obtain a probe pin having a desired shape.

### SUMMARY OF THE INVENTION

Accordingly, it is an object of the present invention to provide a method for manufacturing a probe pin and a method for manufacturing a probe card, which are capable of overcoming the above drawbacks accompanying the convention alert. The above and other objects can be achieved by combinations described in the independent claims. The dependent claims define further advantageous and exemplary combinations of the present invention.

In order to solve the problems above, according to the first aspect of the present invention, a method for manufacturing a probe card comprising a plurality of probe pins electrically connected with a connection terminal provided on a circuit under test for transferring a signal between the circuit under test and a testing apparatus for testing the circuit under test, the method comprises the steps of preparing a probe pin forming substrate for forming the plurality of probe pins, forming an amorphous alloy layer of a predetermined shape at a plurality of areas of the probe pin forming substrate wherein the amorphous alloy layer has a supercooled liquid temperature area, heating the amorphous alloy layer at the supercooled liquid temperature area, cooling the amorphous alloy layer at a temperature lower than the supercooled liquid temperature area, preparing a holding substrate comprising a transfer line for transferring a signal in order to hold the amorphous alloy layer, joining a part of the amorphous alloy layer and the transfer line and removing at least a part of the probe pin forming substrate in a state where the amorphous alloy layer is cooled at a temperature lower than the supercooled liquid temperature area.

The step of preparing the probe pin forming substrate may include a step of forming a probe pin forming groove part having a bottom surface provided to be substantially parallel to a surface of the probe pin forming substrate and an inclined surface having a first end provided to extend from the bottom surface to have an angle to the bottom surface and a second end provided to extend from the surface of the probe pin forming substrate, and the amorphous alloy layer is deposited from the bottom surface over the inclined surface and the surface of the probe pin forming substrate during the step of forming the amorphous alloy layer.

During the step of forming the probe pin forming groove part, the probe pin forming groove part is formed on the probe pin forming substrate by treating the probe pin forming substrate with an isotropic etching.

During the step of preparing the probe pin forming substrate, a protrusion forming groove part is further used for forming a protrusion part at an area where the amorphous alloy layer is formed on the bottom surface, and during the step of forming the amorphous alloy layer, the amorphous alloy layer is formed at the protrusion forming groove part.

The method for manufacturing a probe card may further includes a step of forming a conductive layer on a surface of the amorphous alloy layer.

During the step of joining, a part of the amorphous alloy layer and the transfer line are joined in a state where the supercooled liquid temperature area is heated.

The method for manufacturing a probe card may further comprise a step of forming a joining member for joining the amorphous alloy layer and the transfer line at the amorphous alloy layer or the transfer line, wherein during the step of joining, the amorphous alloy layer and the transfer line are joined via the joining member.

The method for manufacturing a probe card may further comprise a step of dividing the probe pin forming substrate for each of the probe pins, wherein during the step of joining, the amorphous alloy provided on the probe pin forming substrate divided and the transfer line are joined.

According to the second aspect of the present invention, a method for manufacturing a probe pin electrically connected with a connection terminal provided on a circuit under test for transferring signals to the circuit under test, the method comprises the steps of forming an amorphous alloy layer of a predetermined shape on a probe pin forming substrate for forming the probe pin, wherein the amorphous alloy layer has a supercooled liquid temperature area, heating the amorphous alloy layer at the supercooled liquid temperature area, cooling the amorphous alloy layer and removing at least a part of the probe pin forming substrate in a state where the amorphous alloy layer is cooled at a temperature lower than the supercooled liquid temperature area.

The summary of the invention does not necessarily describe all necessary features of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows a probe card 10 in relation to an embodiment of the present invention.

FIGS. 2A to 2I show a method for manufacturing a probe card in relation to the present invention.

FIGS. 3A to 3F show another embodiment of a step of forming a probe pin.

FIGS. 4A to 4D show processes of another embodiment of the method for manufacturing a probe card 10 shown in FIG. 2.

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

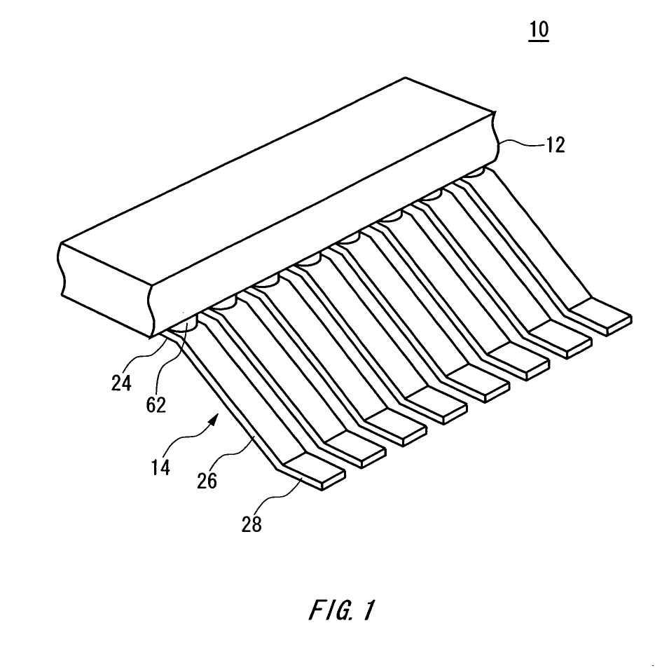

FIG. 1 shows a probe card 10 in relation to an embodiment of the present invention. The probe card 10 has a plurality of probe pins 14 formed of an amorphous alloy having a supercooled liquid temperature area, a probe substrate 12 having a transfer line through which signals are supplied to a terminal being in contact with a probe pin 14 and holding a plurality of probe pins 14, and a joining member 62 for joining the probe pins 14 and the transfer line. The probe card 10 according to the present invention is suitable for, e.g., electrically connecting a testing apparatus for testing a circuit provided in a semiconductor device and connection terminals of the semiconductor device.

The probe pin 14 according to the present invention has a holding end part 24 for holding the probe substrate 12, an inclined part 26 extending from the holding end part 24 and is provided to make a predetermined angle to the holding end part 24, and a free end part 28 extending from the inclined part 26 and is provided to be substantially parallel to the holding end. And, the holding end part 24 is electrically connected with the transfer line provided in the probe substrate 12. Since the free end part 28 is provided to be substantially parallel to the holding end part 24, that is, parallel to the probe substrate 12 and the connection terminal, it is possible to enlarge the area where the free end part 28 and the connection terminal are in contact with each other. Further, it is possible to reduce the contact resistance between the probe pin 14 and the connection terminal, and to supply the test signals to the circuit under test efficiently. In addition, the inclined part 26 has a function as an elastic part for pressing the free end part 28 toward the connection terminal when the free end part 28 of the probe pin 14 is in contact with the connection terminal.

The free end part 28 is in contact with the connection terminal that is provided in, e.g., a semiconductor device electrically. It is preferable that the free end part 28 has a protrusion part for being in contact with the connection terminal. The protrusion part in this case is preferably formed at the free end part 28 by, e.g., plating or jet printing. Since the free end part 28 has the protrusion part, it is possible to electrically connect the probe pin 14 to the connection terminal more securely.

In addition, the free end part 28 included in the plurality of probe pins 14 may be provided at the different height from the probe substrate 12. Since the free end part 28 is provided at the different height, it is possible to press each of the free end parts 28 to the connection terminal with a desired force when the free end part 28 is in contacted with the connection terminal. In addition, even if each of the connection terminals is provided at the different height, it is possible to press the free end parts 28 to the connection terminal with a desired force. Moreover, in another embodiment, since the inclined parts 26 of the plurality of probe pins 14 are provided to have different lengths, each of the free end parts 28 may be pressed to the connection terminal with a desired force.

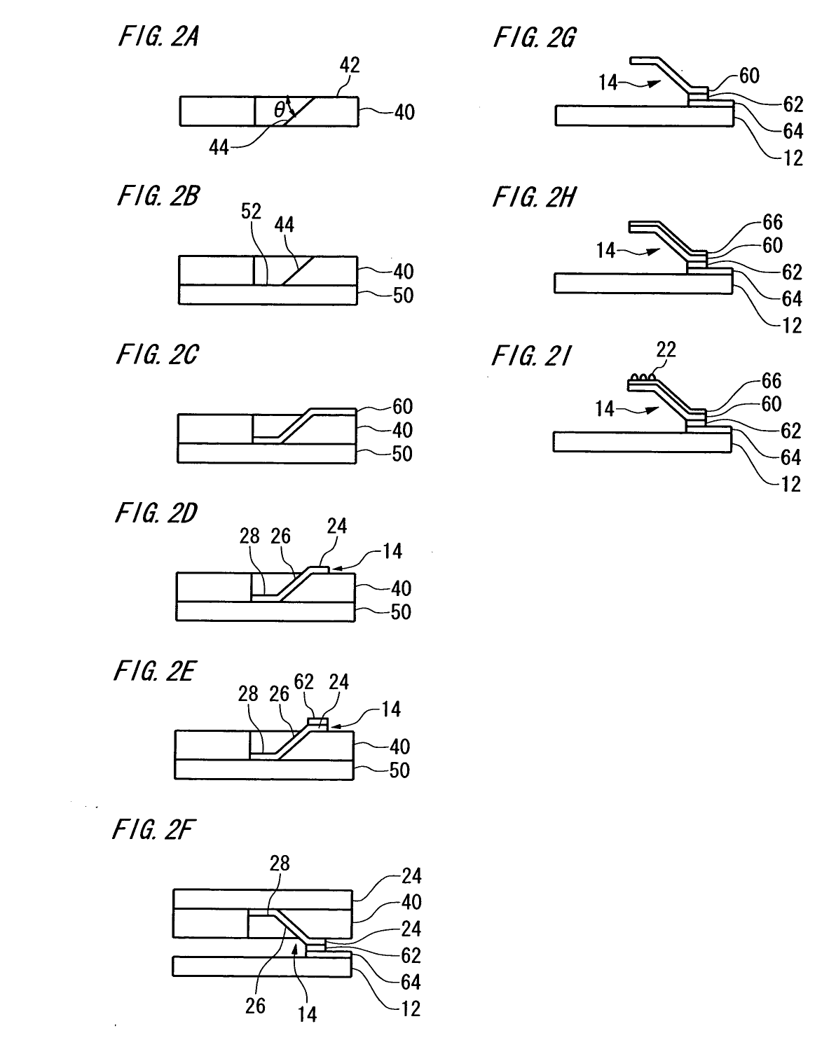

FIG. 2 shows a method for manufacturing a probe card in relation to the present invention. First, as shown in FIG. 2A, a first substrate 40 is prepared, wherein the first substrate 40 has a first plane part 42 for forming the holding end part 24 of the probe pin 14 and an inclined surface part 44 of which an end is provided to extend to the first plane part 42 in order to have a predetermined angle θ to the first plane part 42. It is preferable that the first substrate 40 is a single crystal substrate such as a silicon substrate. It is preferable that the angle θ is within a range of 30 to 60 degrees, and further preferably is 54.7 degrees. In addition, the first substrate 40 preferably has inclined surface parts 44 at each of a plurality of areas on the substrate surface respectively. In this case, each of the plurality of inclined surface parts 44 may be provided at substantially the same surface.

Then, as shown in FIG. 2B, the first substrate 40 is bonded to a second substrate 50 that has a second plane part 52 for forming the free end 18 of the probe pin 14. The second substrate 50 may be, e.g., a silicon substrate. The first substrate 40 and second substrate 50 are preferably bonded in order that the second plane part 52 is provided to extend to the other end of the inclined surface part 44. In addition, the second plane part 52 is preferably parallel to the first plane part 42. And, by bonding the first substrate 40 and the second substrate 50 each other, a probe pin forming groove part is obtained for forming an amorphous alloy layer for constituting the probe pin in a step described below, having the second plane part 52 at a bottom surface and having the inclined surface part 44 at a side surface.

In another embodiment, a substrate may be provided with a probe pin forming groove part having the inclined surface part 44 and the second plane part 52, the bottom surface. In this case, it is preferable that the probe pin forming groove part is formed by treating a substrate with an isotropic etching. In addition, the probe pin forming groove part may be provided in order that all of the side walls become the inclined surface part 44 having a predetermined angle to the first plane part 42.

Continuously, as shown in FIG. 2C, an amorphous alloy layer 60 having a supercooled liquid temperature area is formed on the first substrate 40 and the second substrate 50. The amorphous alloy layer 60 is preferably formed by a sputtering method. In addition, it is preferable that the amorphous alloy layer 60 is formed from the second plane part 52 of the second substrate 50 over inclined surface part 44 and the first plane part 42 of the first substrate 40.

Continuously, the amorphous alloy layer 60 deposited is heated. The amorphous alloy layer 60 is preferably heated until the temperature higher than the glass transition temperature of the amorphous alloy used for the material. In the present invention, the amorphous alloy layer 60 is heated until the supercooled liquid temperature area that is at more than the glass transition temperature of the amorphous alloy and less than the crystallization initiation temperature. After this, the amorphous alloy layer 60 is cooled less than the glass transition temperature by, e.g., cooling naturally.

Since the amorphous alloy layer 60 constituting the probe pin 14 is heated to the supercooled liquid temperature area before peeled off from the first substrate 40 and the second substrate 50 constituting the probe pin forming substrate, it is possible to alleviate the internal stress that occurs in the amorphous alloy layer 60. Therefore, since the amorphous alloy layer 60 deposited to the probe pin forming substrate can be adapted to the probe pin forming substrate, it is possible to obtain a probe pin 14 having substantially the same shape as that at the time formed on the probe pin forming substrate even after the amorphous alloy layer 60 peeled off from the probe pin forming substrate.

In addition, since it is possible to alleviate the internal stress that occurs in the amorphous alloy layer 60 by heating the amorphous alloy layer 60 before removing the probe pin forming substrate, it is possible to alleviate the internal stress that occurs between the amorphous alloy layer 60 and other metal layer by accumulating the amorphous alloy layer 60 and other metal layer even when forming the probe pin. Further, it is possible to obtain the probe pin 14 having a desired shape easily.

Then, as shown in FIG. 2D, by removing an unnecessary part of the amorphous alloy layer 60 with etching, the probe pin having the holding end part 24 for holding the probe substrate, the inclined part 26 functioning as an elastic part of the probe pin and the free end part 28 for being in contact with the terminal is formed. Moreover, in another embodiment, the probe pin 14 may be formed by depositing the amorphous alloy at the first plane part 42 and the inclined surface part 44 of the first substrate 40 and the second plane part 52 of the second substrate 50 by a liftoff method.

Continuously, as shown in FIG. 2E, a joining member 62 is formed at the holding end part 24 of the probe pin 14. The joining member 62 is preferably a metal material not including lead (Pb) such as gold (Au) bump, an Au alloy such as an alloy (AuSn) of gold and tin, solder, an alloy of silver and tin (AgSn). In addition, the joining member 62 is preferably formed by plating or stud bump. Although the joining member 62 is formed at the probe pin 14 in the present embodiment, it may be formed at the transfer line provided in the probe substrate 12 or may be formed at both the transfer line and the probe pin 14 in another embodiment.

Continuously, as shown in FIG. 2F, a probe substrate 12, at which a transfer line 64 including a conducting material is formed, is prepared. Then, the holding end part 24 of the probe pin 14 is joined to the probe substrate 12 via the joining member 62. First, the holding end part 24 is positioned at the probe substrate 12. And, the holding end part 24 is bonded to the probe substrate 12. After this, the holding end part 24 is bonded with the probe substrate 12 by thermal compression. It is preferable that the join of the holding end part 24 to the probe substrate 12 is performed in a series of operations using flip-chip bonding. In addition, the thermal compression bonding is preferably performed at a temperature at which the amorphous alloy layer is not heated to the supercooled liquid temperature area.

In another embodiment, the holding end part 24 and the transfer line 64 may be joined directly without forming the joining member 62. In addition, by heating and bonding at the supercooled liquid temperature area, the amorphous alloy layer may be heated at the supercooled liquid temperature area, and the holding end part 24 may be bonded to the transfer line 64 by thermal compression. In addition, the probe pin forming substrate may be divided for each of the probe pins, and the probe pins 14 provided in the probe pin forming substrate divided may be joined with the transfer line 64 gradually.

Next, as shown in FIG. 2G, the first substrate 40 and the second substrate 50 for removing the first substrate 40 and the second substrate 50 that constituting the probe pin forming substrate are preferably removed by, e.g., wet etching using potassium hydroxide solution or dry etching using XeF2.

In the present embodiment, since the probe pin forming substrate is removed after heating the amorphous alloy for forming the probe pin to the supercooled liquid temperature area and cooling it a temperature lower than the supercooled liquid temperature area, the internal stress in the probe pin itself does not almost occur. In other words, even after removing the probe pin forming substrate, it is possible to hold the shape of the probe pin having a desired shape at the time of being formed on the probe pin forming substrate.

Further, as shown in FIG. 2H, a conductive layer 66 may be formed over the amorphous alloy layer. The conductive layer 66 is preferably formed of, e.g., a material of which the resistance is lower than the amorphous alloy such as Au. Since the conductive layer 66 is formed over the amorphous alloy layer, it is possible to supply the signals to the circuit with which the probe pin is in contact more efficiently.

In another embodiment, in the step of forming the amorphous alloy layer described in relation to FIG. 2C and FIG. 2D, a conductive layer may be further deposited on the amorphous alloy layer deposited on the probe pin forming substrate. In this case, in the step of forming the joining member 62 described in relation to FIG. 2E, the joining member 62 is formed over the conductive layer. And, in the step of joining described in relation to FIG. 2F, the transfer line 64 and the conductive layer constituting the probe pin 14 are joined via the joining member 62.

Continuously, as shown in FIG. 2I, a protrusion part 22 is formed on the free end part 28 of the probe pin 14 to be in contact with the connection terminal. It is preferable that a plurality of protrusion parts 22 is formed on the free end part 28. The protrusion parts 22 are preferably formed by plating or jet printing. Since the free end part 28 has the protrusion parts 22 so that the protrusion parts 22 can scrub the surface of the connection terminal when the probe pin 14 is in contact with the connection terminal, it is possible to allowing the probe pin 14 and the connection terminal to be in contact with each other electrically more securely. In addition, since the first substrate 40 has a plurality of inclined surface parts 44, it is possible to generate the probe card 10 having a plurality of probe pins 14 as shown in FIG. 1.

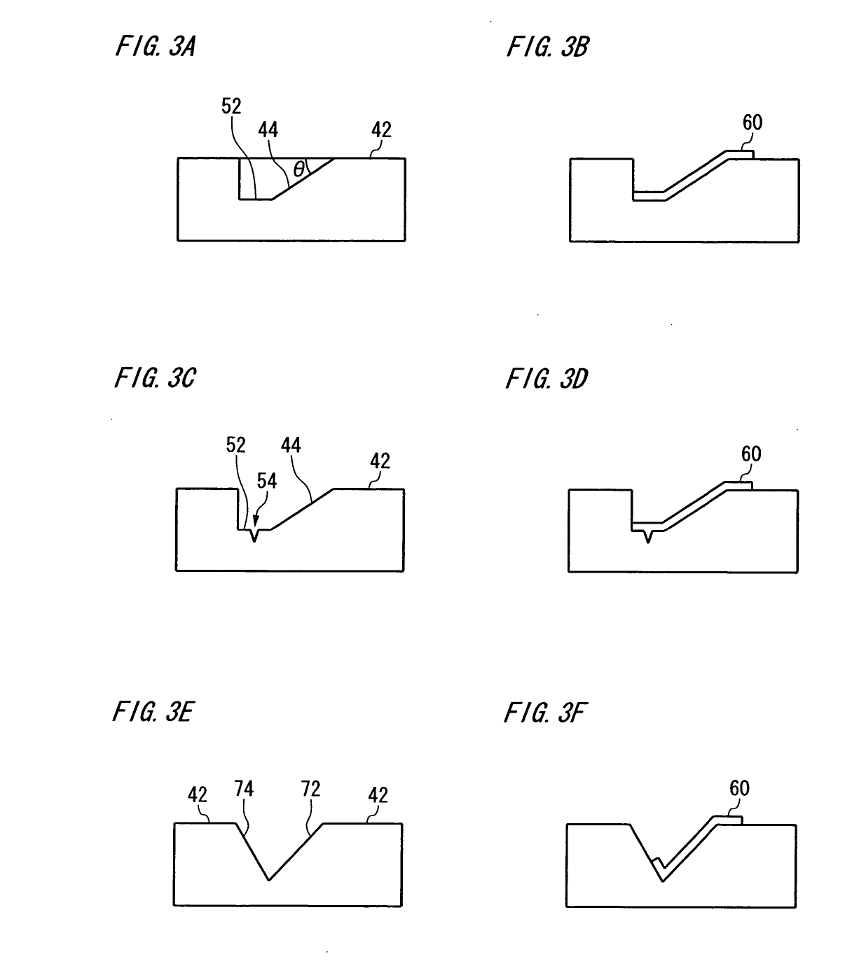

FIG. 3 shows another embodiment of a step of forming the probe pin. As shown in FIG. 3A, the probe pin forming substrate may be a single substrate. In this case, at a first plane part 42 of a probe pin forming substrate, a probe pin forming groove part including a second plane part 52, which is a bottom surface, and an inclined surface part 44 formed between the second plane part 52 and first plane part 42 is formed. Then, as shown in FIG. 3B, the amorphous alloy layer 60 is formed from the first plane part 42 over the inclined surface part 44 and the second plane part 52.

And, as shown in FIG. 3C, a protrusion forming groove part 54 for forming a protrusion part on the probe pin may be formed on the second plane part 52 that is the bottom surface of the probe pin forming groove part provided in the probe pin forming substrate. And, as shown in FIG. 3D, an amorphous alloy layer 60 is formed over the first plane part 42, the inclined surface part 44, the second plane part 52 and the protrusion forming groove part 54.

And, as shown in FIG. 3E, a probe pin forming groove part having a V-shaped section may be formed on the probe pin forming substrate, wherein the probe pin forming groove part includes a first inclined surface part formed to have a first angle to the first plane part 42 and includes a second inclined surface part 98 formed from the first plane part 42 to the first inclined surface part 96 to have a second angle to the first plane part. In this case, the first angle and the second angle may be substantially the same angle. That is, the first inclined surface part 96 and the second inclined surface part 98 may be formed to have the same angel to the first plane part 42 and besides to have the reverse symbol of the angle. And, as shown in FIG. 3F, the amorphous alloy layer 60 is formed from the first plane part 42 over at least a part of the first inclined surface part 96 and the second inclined surface part 98. Since the probe pin forming groove part has a V-shape, it is possible to omit the step of forming the protrusion part.

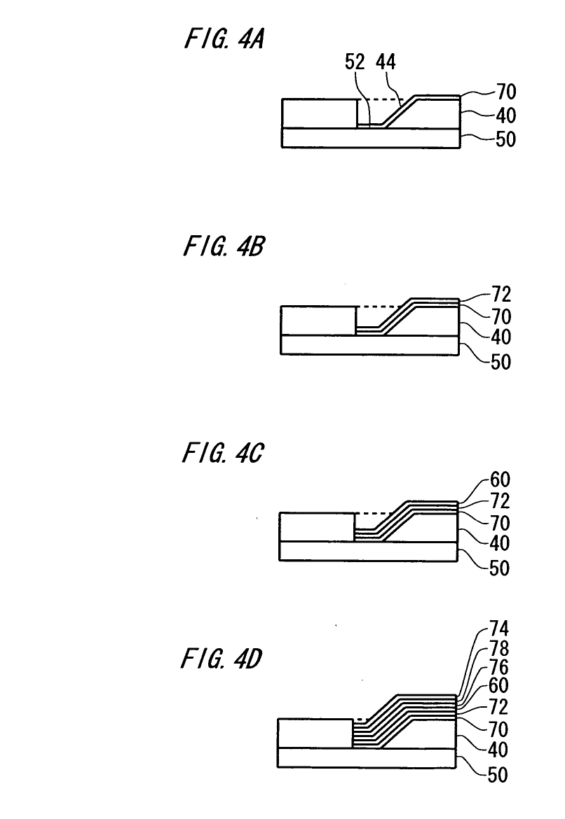

FIG. 4 shows processes of another embodiment of the method for manufacturing the probe card 10 shown in FIG. 2. In the present embodiment, the step of forming the amorphous alloy layer 60 shown in FIG. 2C may include the processes below.

As shown in FIG. 4A, an adhesion layer 70 for allowing the amorphous alloy layer to adhere to a first substrate 40 and a second substrate 50 is formed on a first plane part 42 and an inclined surface part 44 of a first substrate 40 and a second plane part 52 of the second substrate 50. If the amorphous alloy consists of mainly palladium, it is preferable that the adhesion layer 70 includes titan nickel alloy of which the composition rate is 1:1. If the amorphous alloy contains copper mainly consisting of palladium, the adhesion layer 70 may have a first adhesion layer including chrome or titan and a second adhesion layer including copper. It is preferable that the first adhesion layer is formed over the first substrate 40 and the second substrate 50 and the second adhesion layer is formed over the first adhesion layer.

Continuously, as shown in FIG. 4B, a peeling-off sacrifice layer 72 is formed over the adhesion layer 70 in order to make it easy to remove the first substrate 40 and the second substrate 50 from the probe pin 14 during the following process. The peeling-off sacrifice layer 72 is preferably formed of a material to endure heating or chemical treatment such as etching in regard to the amorphous alloy layer during the following process. The peeling-off sacrifice layer 72 is preferably a metal film. In the present embodiment, the peeling-off sacrifice layer 72 is formed to have the thickness of approximately 100 nm including chrome.

In the present embodiment, the step of peeling off the amorphous alloy layer 60 shown in FIG. 2G from the first substrate 40 and the second substrate 50 peels off the amorphous alloy layer 60 from the first substrate 40 and the second substrate 50 by removing the peeling-off sacrifice layer 62 with etching.

As shown in FIG. 4C, the amorphous alloy layer 60 is formed over the peeling-off sacrifice layer 72. Next, as shown in FIG. 4D, the metal layer 74 is formed over the amorphous alloy layer 60. Further, the adhesion layer 76 for allowing the amorphous alloy layer 60 and the metal layer 74 to adhere may be formed over the amorphous alloy layer 60. If the amorphous alloy consists mainly of palladium in the adhesion layer 76, like the adhesion layer 70, the adhesion layer 76 preferably includes titan nickel alloy of which the composition rate is 1:1. If the amorphous alloy contains copper mainly consisting of palladium, the adhesion layer 76 may have a first adhesion layer including chrome or titan and a second adhesion layer including copper.

In addition, a barrier layer 78 may be formed between the amorphous alloy layer 60 and the metal layer 74 in order to prevent a metal included in the metal layer 74 from diffusing into the amorphous alloy layer 60. In the present embodiment, the barrier layer 78 may be provided between the adhesion layer 76 and the metal layer 74. The barrier layer 78 is preferably platinum. The barrier layer 78 is preferably about 100 nm. Since the barrier layer 78 is formed between the amorphous alloy layer 60 and the metal layer 74, a metal included in the metal layer 74 does not diffuse into the amorphous alloy layer 60 even if the amorphous alloy layer 60 is heated. If the barrier layer 78 of platinum is formed over the adhesion layer 76, the adhesion layer 76 may uses only the second adhesion layer including copper.

Further, an adhesion layer for allowing the barrier layer 78 and the metal layer 74 to adhere may be formed between the barrier layer 78 and the metal layer 74 as well. In addition, the probe pin 14 may have both the conductive layer 66 shown in FIG. 2H and the metal layer 74 shown in FIG. 4D or have only one of them.

It is preferable to perform the step of forming the adhesion layer 70, the step of forming the peeling-off sacrifice layer 72, the step of forming the amorphous alloy layer 60, the step of forming the adhesion layer 76, the step of forming the barrier layer 78 and the step of forming the metal layer 74 in the same apparatus by the sputtering method.

Although the present invention has been described by way of exemplary embodiments, it should be understood that those skilled in the art might make many changes and substitutions without departing from the spirit and the scope of the present invention, which is defined only by the appended claims.

As obvious from the description above, according to the present invention, it is possible to provide the probe pin and the probe card formed to have the desired shape with high precision.

What is claimed is:

1. A method for manufacturing a probe card, which comprises a plurality of probe pins electrically connected with a connection terminal provided on a circuit under test for transferring a signal between said circuit under test and a testing apparatus for testing said circuit under test, comprising the steps of:
preparing a probe pin forming substrate for forming said plurality of probe pins;
forming an amorphous alloy layer of a predetermined shape on a plurality of areas of said probe pin forming substrate, wherein said amorphous alloy layer has a supercooled liquid temperature area;
heating said amorphous alloy layer at said supercooled liquid temperature area;
cooling said amorphous alloy layer at a temperature lower than said supercooled liquid temperature area;
preparing a holding substrate comprising a transfer line for transferring a signal in order to hold said amorphous alloy layer;
joining a part of said amorphous alloy layer and said transfer line; and
removing at least a part of said probe pin forming substrate in a state where said amorphous alloy layer is cooled at a temperature lower than said supercooled liquid temperature area.

2. A method for manufacturing a probe card as claimed in claim 1, wherein said step of preparing said probe pin forming substrate comprises a step of forming a probe pin forming groove part having a bottom surface provided to be substantially parallel to a surface of said probe pin forming substrate and an inclined surface having a first end provided to extend from said bottom surface to have an angle to said bottom surface and a second end provided to extend from said surface of said probe pin forming substrate, and
said amorphous alloy layer is deposited from said bottom surface over said inclined surface and said surface of said probe pin forming substrate during said step of forming said amorphous alloy layer.

3. A method for manufacturing a probe card as claimed in claim 2, wherein said probe pin forming groove part is formed on said probe pin forming substrate by treating said probe pin forming substrate with an isotropic etching during said step of forming said probe pin forming groove part.

4. A method for manufacturing a probe card as claimed in claim 2, wherein said step of preparing said probe pin forming substrate further comprises a step of forming a protrusion forming groove part used for forming a protrusion part at an area where said amorphous alloy layer is formed on said bottom surface, and
said amorphous alloy layer is formed at said protrusion forming groove part during said step of forming said amorphous alloy layer.

5. A method for manufacturing a probe card as claimed in claim 1 or 2, further comprising a step of forming a conductive layer on a surface of said amorphous alloy layer.

6. A method for manufacturing a probe card as claimed in claim 1 or 2, wherein a part of said amorphous alloy layer and said transfer line are joined in a state where said supercooled liquid temperature area is heated during said step of joining.

7. A method for manufacturing a probe card as claimed in claim 1 or 2, further comprising a step of forming a joining member for joining said amorphous alloy layer and said transfer line at said amorphous alloy layer or said transfer line, wherein said amorphous alloy layer and said transfer line are joined via said joining member during said step of joining.

8. A method for manufacturing a probe card as claimed in any one of claims 1 to 8, further comprising a step of dividing said probe pin forming substrate for each of said probe pins, wherein said amorphous alloy provided on said probe pin forming substrate divided and said transfer line are joined during said step of joining.

9. A method for manufacturing a probe pin electrically connected with a connection terminal provided on a circuit under test for transferring signals to said circuit under test, said method comprising the steps of:
forming an amorphous alloy layer of a predetermined shape on a probe pin forming substrate for forming said probe pin, wherein said amorphous alloy layer has a supercooled liquid temperature area;
heating said amorphous alloy layer at said supercooled liquid temperature area;
cooling said amorphous alloy layer; and
removing at least a part of said probe pin forming substrate in a state where said amorphous alloy layer is cooled at a temperature lower than said supercooled liquid temperature area.
